(19) United States
(12) Patent Application Publication
(10) Pub. No.: US 2026/0304860 A1
(43) Pub. Date: Oct. 1, 2026

(54) SUPERJUNCTION TRANSISTOR DEVICE AND METHOD

(71) Applicant: Infineon Technologies Austria AG, Villach (AT)

(72) Inventors: Christian Fachmann, Villach (AT); Winfried Kaindl, Unterhaching (DE); Franz Hirler, Isen (DE); Markus Rochel, Radebeul (DE); Hans Weber, Villach (AT)

(21) Appl. No.: 19/631,220

(22) Filed: Mar. 27, 2026

(30) Foreign Application Priority Data
Mar. 28, 2025 (DE) 102025112319.5

(51) Int. Cl. H10D 62/10; H10D 30/01; H10D 30/66; H10D 62/00; H10D 64/00

(52) U.S. Cl. CPC H10D 62/111; H10D 30/0297; H10D 30/665; H10D 30/668; H10D 62/054; H10D 62/127; H10D 64/117

(57) ABSTRACT

A transistor device includes: a superjunction region including first regions of a first doping type and second regions of a second complementary doping type, the first and second regions being arranged alternately in a lateral direction of a semiconductor body; transistor cells each including a gate electrode arranged in a gate trench and dielectrically insulated from the semiconductor body by a gate dielectric, a source region, and a body region; and a trench electrode arrangement including a trench electrode grid arranged in a grid-shaped trench of the semiconductor body and insulated from the semiconductor body by a dielectric layer. The trench electrode grid includes: longitudinal electrodes spaced apart from each other in a first lateral direction of the semiconductor body and connection electrodes each connecting two adjacent longitudinal electrodes. The gate electrodes of at least some transistor cells are formed by the longitudinal electrodes of the trench electrode grid.

### TECHNICAL FIELD

This disclosure relates in general to a superjunction transistor device and a method for forming a superjunction transistor device.

### BACKGROUND

A superjunction transistor device includes a superjunction region with a plurality of first regions of a first doping type coupled to the drain region and a plurality of second regions of a second doping type complementary to the first doping type coupled to the source node.

### SUMMARY

One example relates to a transistor device. The transistor device includes: a superjunction region including first regions of a first doping type and second regions of a second doping type complementary to the first doping type, the first regions and the second regions being arranged alternately in a lateral direction of a semiconductor body; transistor cells each including a gate electrode arranged in a gate trench and dielectrically insulated from the semiconductor body by a gate dielectric, a source region, and a body region; and a trench electrode arrangement including a first trench electrode grid arranged in a grid-shaped trench of the semiconductor body and insulated from the semiconductor body by a dielectric layer. The first trench electrode grid includes: first longitudinal electrodes spaced apart from each other in a first lateral direction of the semiconductor body and first connection electrodes each connecting two adjacent first longitudinal electrodes. The gate electrodes of at least some of the transistor cells are formed by the first longitudinal electrodes of the trench electrode grid.

Another example relates to a method. The method includes: forming a superjunction region in a semiconductor body, the superjunction region including first regions of a first doping type and second regions of a second doping type complementary to the first doping type; and forming a plurality of transistor cells. Forming each transistor cell includes: implanting second type dopant atoms in a region between a first surface of the semiconductor body and the superjunction region to form a first implanted body region; forming a gate trench extending from the first surface through the first implanted region to the superjunction region; forming a gate dielectric in the gate trench, forming the gate dielectric including a thermal oxidation process that causes a first body region portion to be formed based on the first implanted body region; forming a gate electrode in the gate trench on top of the gate dielectric; and forming a source region in the semiconductor body, the source region adjoining the gate dielectric.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a vertical cross-sectional view of a superjunction transistor device including transistor cells and a superjunction region;

FIG. 2 schematically illustrates a horizontal cross-sectional view of the superjunction region according to one example;

FIG. 3 schematically illustrates a horizontal cross-sectional view of a trench electrode arrangement including a trench electrode grid with longitudinal electrodes and connection electrodes arranged in a grid-shaped trench, the longitudinal electrodes forming gate electrodes of the transistor cells;

FIGS. 4-6 schematically illustrate trench electrode arrangements according to different examples;

FIGS. 7-8 illustrates examples of transistor cells in greater detail;

FIGS. 9-10 illustrate top views of transistor devices according to different examples;

FIG. 11 illustrates a vertical cross-sectional view of one gate electrode and illustrates one example of how the gate electrode can be connected to a gate node;

FIG. 12 illustrates a vertical cross-sectional view of a superjunction transistor device according to another example;

FIGS. 13-14 schematically illustrates horizontal cross-sectional views of trench electrode arrangements including a first trench electrode grid and a second trench electrode grid according to different examples;

FIGS. 15-16 illustrate one example of how the second trench electrode grid can be connected to a source node of the transistor device;

FIG. 17 illustrates another example of how the second trench electrode grid can be connected to the source node;

FIG. 18 illustrates one example of how the second trench electrode grid can be connected to the gate node;

FIG. 19 illustrates one example for forming the superjunction region;

FIGS. 20A-20G illustrate one example of a method for forming the transistor cells;

FIGS. 21A-21B and 22A-22D illustrate examples for forming gate electrodes of the transistor cells;

FIG. 23 illustrates one example for forming a gate dielectric;

FIGS. 24A-24B illustrate one example of a method for forming portions of body regions of the transistor cells;

FIGS. 25A-25B illustrate one example of a method for forming a gate finger and for connecting the gate finger to a gate electrode; and

FIGS. 26A-26B illustrate one example of a sacrificial oxidation process.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

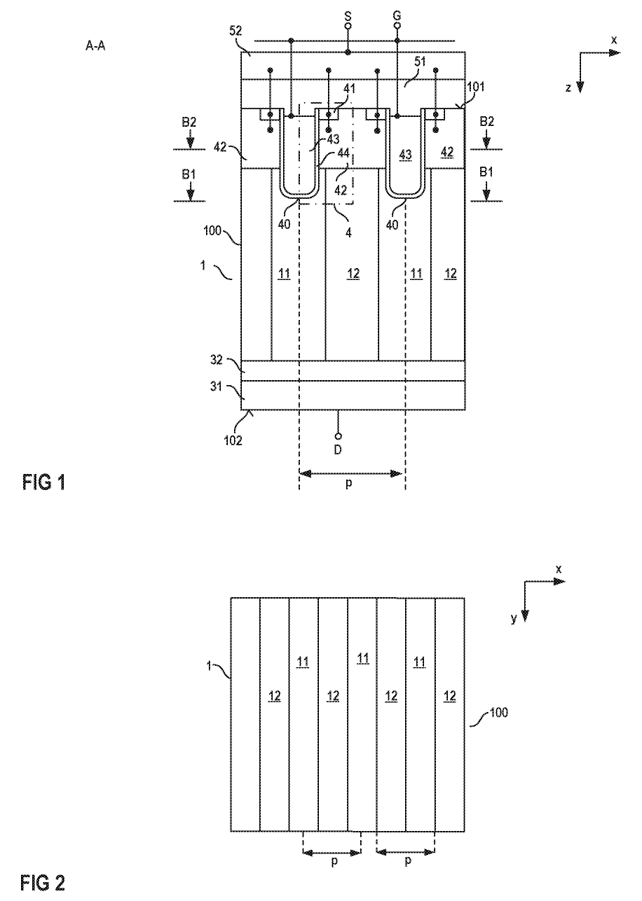

FIG. 1 schematically illustrates a superjunction transistor device according to one example. More specifically, FIG. 1 schematically illustrates a vertical cross-sectional view of a part of the transistor device. The transistor device includes a semiconductor body 100 with a first surface 101 and a second surface 102 opposite the first surface. FIG. 1 illustrates a vertical cross-sectional view of the semiconductor body 100 in a vertical section plane A-A which is substantially perpendicular to the first and second surfaces 101, 102.

According to one example, the semiconductor body 100 includes a monocrystalline semiconductor material. The monocrystalline semiconductor material is silicon (Si) or silicon carbide (SiC), for example.

The semiconductor body 100 further includes a first lateral direction x and a second lateral direction y, the second lateral direction y being substantially perpendicular to the first lateral direction x. The first and second lateral directions are substantially parallel to the first and second surfaces 101, 102 and perpendicular to the vertical direction z. With regard to the first lateral direction x it should be noted that, unless stated otherwise, "first lateral direction x" includes both the direction as indicated by the arrow labelled with x in the figures and the opposite direction. The same applies to the second lateral direction y, which includes both the direction as indicated by the arrow labelled with y in the figures and the opposite direction, and the vertical direction z, which includes both the direction as indicated by the arrow labelled with z in the figures and the opposite direction.

Referring to FIG. 1, the superjunction transistor device includes a superjunction region 1. The superjunction region 1 includes first regions 11 of a first doping type and second regions 12 of a second doping type complementary to the first doping type. The first regions 11 and the second regions 12 are arranged alternately in a first lateral direction x of the semiconductor body 100. The first regions 11 of the superjunction region 1 may also be referred to as a drift regions and the second regions 12 may also be referred to as compensation regions.

According to one example illustrated in FIG. 2, the first and second regions 11, 12 are elongated in the second lateral direction y. FIG. 2 schematically illustrates a horizontal cross-sectional view of the transistor device of the type illustrated in FIG. 1 in a horizontal sectional plane B1-B1 that intersects the superjunction region 1 with the first and second regions 11, 12.

Referring to FIG. 1, the superjunction transistor device further includes a plurality of transistor cells 4. Each transistor cell 4 includes a source region 41 of the first doping type, a body region 42 of the second doping type (complementary to the first doping type), and a gate electrode 43. The gate electrode 43 is adjacent to the body region 42, is dielectrically insulated from the body region 42 by a gate dielectric 44 and is arranged in a gate trench 40 extending from the first surface 101 of the semiconductor body 100 into the semiconductor body 100.

Referring to FIG. 1, source and body regions 41, 42 of two neighboring transistor cells 4 may be arranged in a mesa region between neighboring gate trenches 40. In this example, the body regions 42 of the two neighboring transistor cells 4 may be formed by one contiguous doped region of the second doping type. Furthermore, two (other) neighboring transistor cells may share the gate electrode 43. That is, the gate electrodes 43 of two neighboring transistor cells may be formed by one contiguous electrode arranged in one gate trench 40.

The gate electrodes 43 include an electrically conductive material. Examples of the electrically conductive material include doped polysilicon, or a metal. The gate dielectric 44 includes an oxide, for example. According to one example, the oxide is silicon oxide (SiO₂).

The transistor device further includes a gate node G connected to the gate electrodes 43 of the transistor cells, and a source node S connected to the source and body regions 41, 42 of the transistor cells 4. Connections between the gate node G and the gate electrodes 43 are only schematically illustrated in FIG. 1. An example of how to connect the gate electrodes 43 to the gate node G is explained herein further below.

Referring to FIG. 1, the transistor device may include a source electrode 52 formed above the first surface 101 of the semiconductor body 100 and separated from the semiconductor body 100 and the gate electrodes 43 by an insulating layer 51. The source electrode 52 either forms the source node S or is connected to the source node S and is electrically connected to the source and body regions 41, 42 of the transistor cells 40. Connections between the source electrode 52 and the source and body regions 41, 42 are only schematically illustrated in FIG. 1. Examples of how to connect the source electrode 52 to the source and body regions 41, 42 are explained herein further below.

Referring to FIG. 1, the transistor device may further include a drain region 31 of the first doping type. The drain region 31 is arranged between the superjunction region 1 and the second surface 102 and may adjoin the second surface 102. The drain region 31 forms a drain node D or is connected to a drain node D of the transistor device.

According to one example, as illustrated in FIG. 1, the drain region 31 is spaced apart from the superjunction region 1 in the vertical direction z. In this example, a buffer region 32 of the first doping type is arranged between the drain region 31 and the first and second superjunction regions 1, 2. A doping concentration of the buffer region 32 is lower than a doping concentration of the drain region 31, such as more than two orders of magnitude lower than the doping concentration of the drain region 31. The drain region 31 and the optional buffer region 32 couple (connect) the first regions 11 of the superjunction region 1 to the drain node D of the transistor device.

The second regions 12 of the first superjunction region 1 are coupled to the source node S. In the example illustrated in FIG. 1, each of the second regions 12 adjoins the body region 42 of a respective transistor cell 4 and is coupled to the source node S via the body region 42 of the transistor cell 4. Furthermore, the first regions 11 of the superjunction region 1 are coupled to the drain node D via the drain region 31 and the optional buffer region 32.

The transistor device can be operated in the on-state or the off-state. The transistor device is in the on-state when a voltage (gate-source voltage) applied between the gate node G and the source node S is such that a conducting channel is generated in each transistor cell 4 by the gate electrode 43 in the body region 42 along the gate dielectric 44. The transistor device is in the off-state when the conducting channel is interrupted.

Each transistor cell 4 is connected between the source node S and at least one of the first regions 11, so that a current can flow from the source node S through the transistor cells 4 and the first regions 11 to the drain node D when the transistor device is in the on-state. To enable such current flow from the source node S to the drain node D when the transistor device is in the on-state, the gate trench 40 with the gate electrode 43 and the gate dielectric 44 of each transistor cell 4, in the vertical direction z of the semiconductor body 100, extends into a respective one of the first regions (drift regions) 11. In this way, in the on-state, charge carriers can move from the source regions 41 along the conducting channels in the body regions 42, the first regions 11 of the first superjunction region 1, the optional buffer region 52 and the drain region 51 to the drain node D.

When the transistor device is in the off-state and a voltage is applied between the drain node D and the source node S space, charge regions (depletion regions) expand in the first regions 11 and the second regions 12 beginning at PN junctions formed between adjacent first and second regions 11, 12. This enables the first superjunction region 1 to substantially absorb the voltage applied between the drain node D and the source node S of the transistor device. This is a well-known operating principle of superjunction devices, so that no further explanation is required in this regard.

According to one example, the transistor device is an N-type transistor device. In this example, the regions of the first doping type, such as the drain and buffer regions 51, 52, the first and third regions 11, 13, the first termination region 31 and the source regions 41 are N-type regions and the regions of the second doping type, such as the second and fourth regions 12, 22 and the second termination region 32 are P-type regions. An N-type transistor device is in the forward biased mode when a positive voltage is applied between the drain node D and the source node S. N-type dopant atoms for forming N-type regions are phosphorus (P) atoms, for example, and P-type dopant atoms for forming P-type regions are boron (B) atoms, for example.

According to another example, the transistor device is a P-type transistor device. In this example, the regions of the first doping type are P-type regions and the regions of the second doping type are N-type regions.

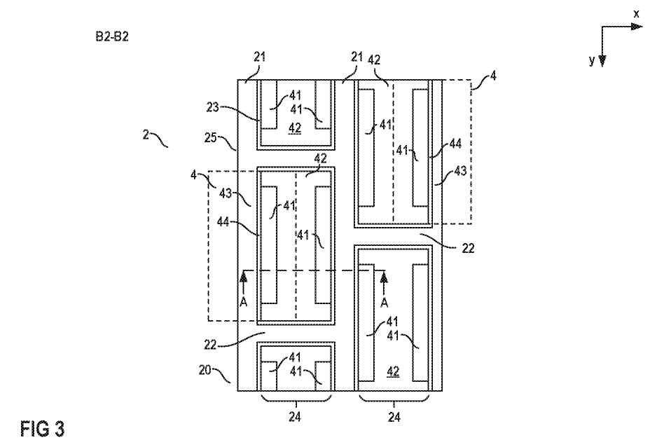

According to one example illustrated in FIG. 3, the transistor device includes a trench electrode arrangement 20 with a trench electrode grid 20. FIG. 3 shows a horizontal cross-sectional view in a horizontal section plane B2-B2 intersecting the transistor cells 4.

Referring to FIG. 3, the trench electrode grid 20 is arranged in a grid-shaped trench 25 of the semiconductor body 100 and is insulated from the semiconductor body 100 by a dielectric layer. The trench electrode grid 20 includes longitudinal electrodes 21 spaced apart from each other in a lateral direction of the semiconductor body, and connection electrodes each connecting two adjacent first longitudinal electrodes. According to one example, the lateral direction in which the longitudinal electrodes 21 are spaced apart from each other is the first lateral direction x in which the first and second regions 11, 12 of the superjunction region 1 are arranged alternately. In this example, the longitudinal electrodes 21 are elongated in a second lateral direction y perpendicular to the first lateral direction x.

Referring to FIG. 3, the longitudinal electrodes 21 form the gate electrodes 43 of the transistor cells 4 and the dielectric layer 23 insulating the longitudinal electrodes 21 from the semiconductor body 100 form the gate dielectric 44. The source regions 41 are arranged in openings 24 of the trench electrode grid 20 and extend along the longitudinal electrodes 21. According to one example, the source regions are spaced apart from the connection electrodes 22 and those portions of the dielectric layer 23 separating the connection electrodes 22 from the semiconductor body 100.

As explained herein further below, the longitudinal electrodes 21 forming the gate electrodes 43 of the transistor cells 4 can be connected to the gate node at longitudinal ends. By connecting the longitudinal electrodes with 21 each other by the connection electrodes 22 a low gate resistance of the individual transistor cells 4 can be achieved. The gate resistance of one transistor cell 4 is the electrical resistance between the gate electrode 43 of the respective transistor cell 4 and the gate node G.

Furthermore, connecting the longitudinal electrodes 21 by the connection electrodes 22 makes it possible to even drive transistor cells 4 connected to a longitudinal electrode 21 which, due to a failure in the manufacturing process, may not have been connected to the gate node G.

A center-to-center distance of adjacent longitudinal electrodes 21 defines a pitch p of cell field including the transistor cells 4. According to one example, the pitch p is selected from between 3 micrometers and 4.5 micrometers, in particular between 3 micrometers and 4 micrometers.

According to one example, the pitch p of the transistor cells 4 equals a pitch of the superjunction region 1. The pitch of the superjunction region 1 is substantially given by a center-to-center distance of adjacent first regions 11 or adjacent second regions 12 or by a dimension of a first region 11 plus a dimension of an adjacent second region 12 in the first lateral direction x.

According to one example, a mutual distance of adjacent connection regions 22 in the second lateral direction y is selected from between 30 micrometers and 200 micrometers, in particular between 40 micrometers and 100 micrometers or between 40 micrometers and 60 micrometers.

FIG. 3 illustrates a horizontal cross-sectional view of one portion of the trench electrode grid 20 in detail, wherein the longitudinal electrodes 21, the connection electrodes 22, the dielectric layer 24 insulating the longitudinal electrodes 21 and the connection electrodes 22 from the semiconductor body 100, the body regions 42 formed in grid openings 24 of the trench electrode grid and the source regions 41 are illustrated.

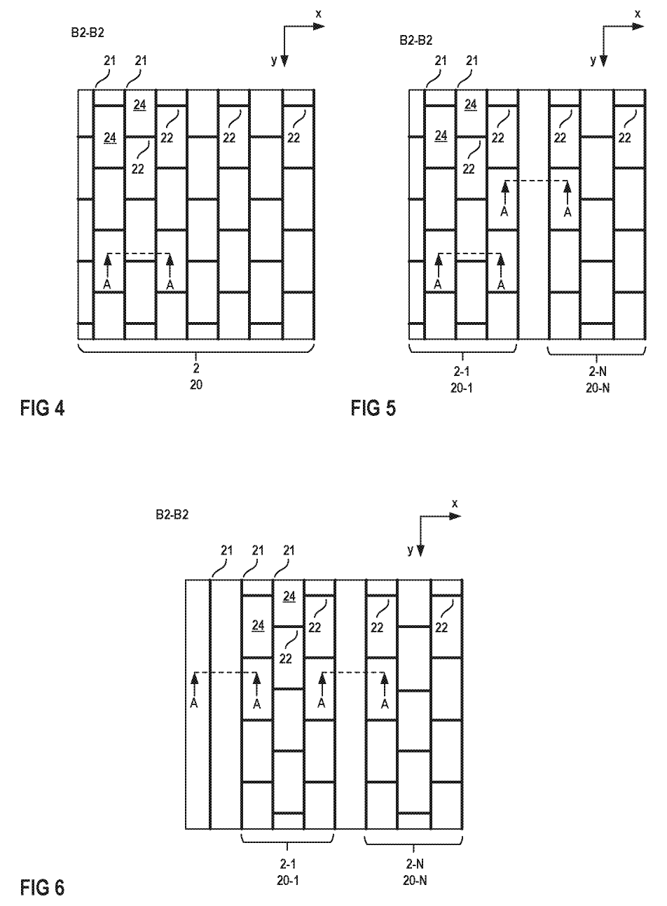

FIG. 4 schematically illustrates a horizontal cross-sectional view of a larger portion of a trench electrode grid 20 of the type illustrated in FIG. 3. For the purpose of illustration, only the longitudinal electrodes 21, the connection electrodes 22 and grid openings 24 are illustrated.

As can be seen from FIGS. 3 and 4, the connection electrodes 22 may be formed such that connection electrodes 22 connected to the same longitudinal electrodes 21 on opposite sides in the first lateral direction x are spaced apart from each other, so that each connection electrode 22 and the longitudinal electrode 21 connected to the connection electrode 21 form a T-shaped electrode section (are connected at a T-crossing).

The transistor device may include only one trench electrode arrangement 2 with a plurality of longitudinal electrodes 21 connected with each other by connection electrodes 22, so that the gate electrodes 43 of each of the transistor cells 4 are formed by the longitudinal electrodes 21 of the one trench electrode arrangement 2.

According to another example illustrated in FIG. 5, the transistor device includes two or more trench electrode arrangements 2-1, 2-N each including a trench electrode grid 20-1, 20-N with two or more longitudinal electrodes 21 connected with each other by connection electrodes 22. The two or more trench electrode arrangements 2-1, 2-N are spaced apart from each other in the first lateral direction. The trench electrode grids 20-1, 20-N of the two or more trench electrode arrangements 2-1, 2-N can be regarded as one grid, where the connection electrodes 22 between two adjacent longitudinal electrodes 21 of one or more pairs of adjacent longitudinal electrodes 21 are omitted. In the space between the adjacent longitudinal electrodes 21 that are not connected by connection electrodes 22 transistor cells can be implemented in the same way as illustrated in FIG. 1.

In addition to one or more trench electrode arrangements each including a trench electrode grid, the transistor device may further include one or more longitudinal electrodes 21 not connected to any other longitudinal electrode by connection electrodes 22. This is illustrated in FIG. 6.

Just for the purpose of illustration, FIG. 6 illustrates a transistor device that includes two trench electrode arrangements 2-1, 2-N with a respective trench electrode grid 20-1, 20-N and an additional longitudinal electrode 21 not connected to any other of the longitudinal electrodes 21.

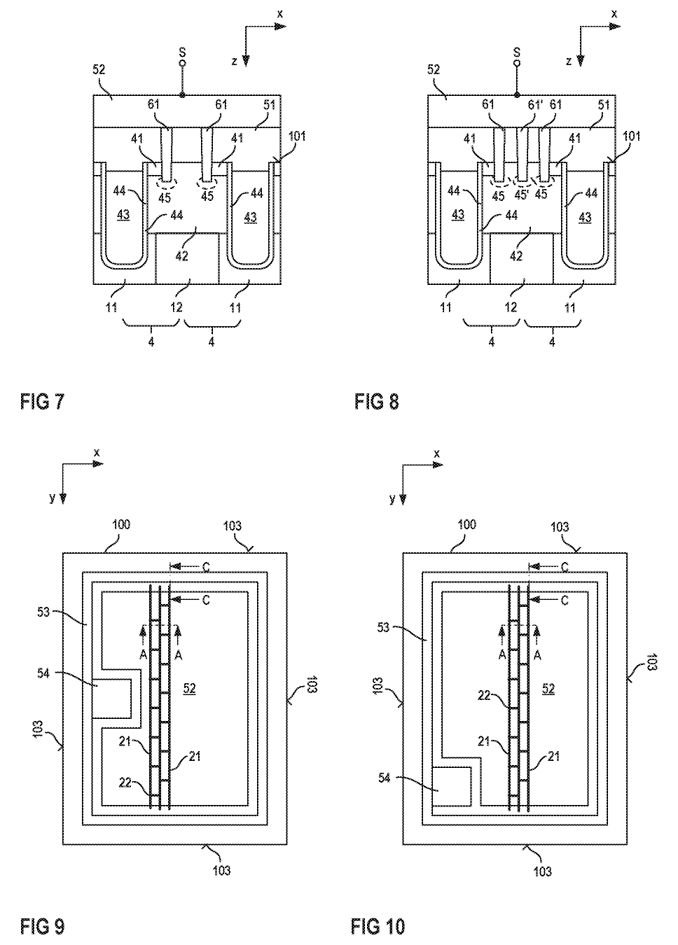

Referring to the above, the source and body regions 41, 42 of the transistor cells 4 are connected to the source electrode 52. Examples of how the source and body regions 41, 42 can be connected to the source electrode 52 are illustrated in FIGS. 7 and 8, each of which illustrates a vertical cross-sectional view of two adjacent transistor cells 4.

According to one example illustrated in FIG. 7 the source region 41 and the body region 42 of each transistor cell 4 is connected to the source electrode 52 by an electrically conducting via 61. The electrically conducting via 61 extends from the source electrode 52 through the insulating layer 51 into the semiconductor body 100 to the source region 41 and the body region 42.

According to one example illustrated in dashed lines in FIG. 7, the via 61 is connected to the body region 42 by a connection region 45 of the second doping type. The connection region 45 provides for an ohmic contact between the rear 61 and the body region 42 and may have a higher doping concentration than the remainder of the body region 42.

FIG. 8 illustrates a modification of the transistor device according to FIG. 7. In the example illustrated in FIG. 8, a further electrically conducting via 61' is connected by a further connection region 45' only to the doped region of the second doping type forming the body regions 42 of the adjacent transistor cells 4. The presence of the further electrically conducting via 61' reduces the electrical resistance between the body region 42 and the source electrode 52 and the helps to increase the robustness of the transistor device against latch-up.

Referring to the above, the longitudinal electrodes 21 of the trench electrode grid 20 may be connected to the gate node G at one or both of their longitudinal ends. The longitudinal ends terminate each longitudinal electrode 21 in the longitudinal direction, which equals the second lateral direction y in the examples explained herein before. Examples of how the longitudinal electrodes 21 of the trench electrode grid 20 may be connected to the gate node G are illustrated in FIGS. 9 and 10, each of which schematically illustrates a top view of a transistor device according to one example. More specifically, each of FIGS. 9 and 10 schematically illustrates a top view of the semiconductor body 100 with the source electrode 52 formed above the first surface 101.

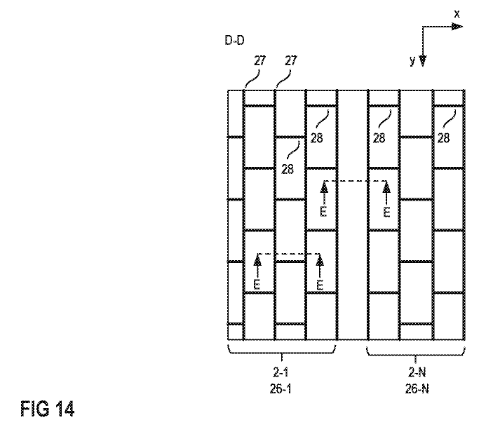

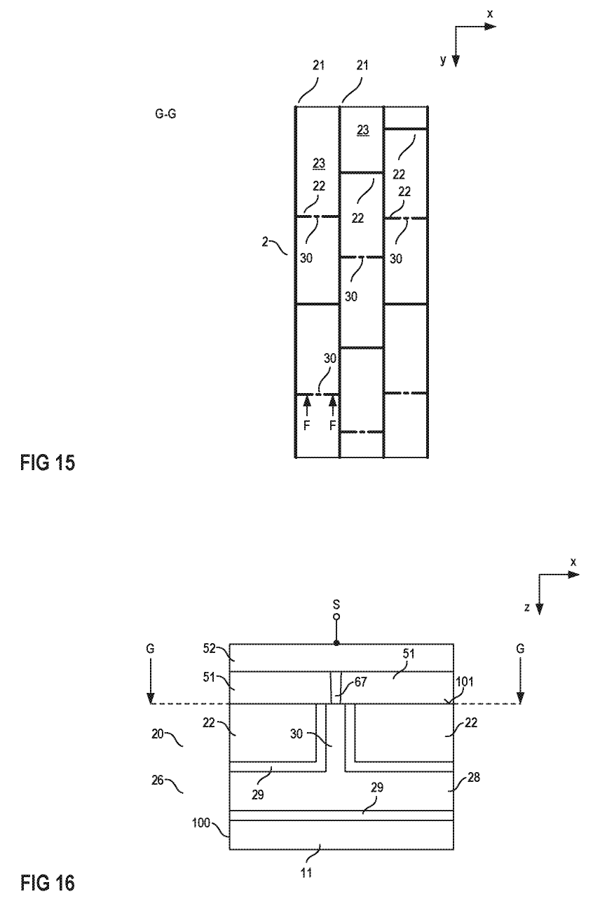

Referring to FIGS. 9 and 10, the transistor device further includes a gate runner 53 and a gate pad 54 both formed on top of the insulating layer 51 and spaced apart from the source electrode 52. The gate runner 53 surrounds the source electrode 52 in lateral directions of the semiconductor body 100. The gate pad 54 forms the gate node G or is connected to the gate node G of the transistor device. The gate pad 54 may adjoin the gate runner 53, as illustrated in FIGS. 14 and 15. Alternatively, the gate pad 54 is spaced apart from the gate runner 53 and a resistor (gate resistor) is connected between the gate pad 54 and the gate runner 53.

In the example illustrated in FIG. 9, the gate pad 54 is arranged at a position that is essentially in the middle between two opposing sidewalls 103 of the semiconductor body 100. In the example according to FIG. 10, the gate pad 54 is arranged at a position that is close to a corner formed by two adjacent sidewalls 103 of the semiconductor body 100. The sidewalls 103 terminate the semiconductor body 100 in lateral directions.

The transistor cells are out of view in FIGS. 9 and 10. For the purpose of illustration, the position of three longitudinal electrodes 21 and corresponding connection electrodes 22 are illustrated in FIGS. 9 and 10. The vertical cross-sectional view of the transistor cells illustrated in FIG. 1 is a cross-sectional view in section planes A-A illustrated in FIGS. 9 and 10, for example.

In order to connect the gate electrodes 43 to the gate pad 54, regions of the gate electrodes 43 close to longitudinal ends of the gate electrodes 43 protrude from the source electrode 52 in the second lateral direction y and are connected to the gate runner 54.

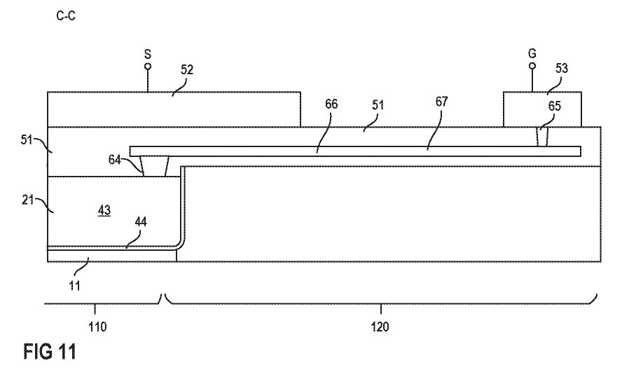

One example of how the gate electrodes 43 can be connected to the gate runner 53 is illustrated in FIG. 11.

FIG. 11 shows a vertical cross-sectional view of the transistor device in a section plane C-C (see also FIGS. 9 and 10) that intersects one longitudinal electrode 21 in the longitudinal direction in the region of one longitudinal end. In this example, the longitudinal end of the gate electrode 43 is connected to the gate runner 53 by a gate finger 66 arranged in the insulating layer 51. The gate finger 66 may be connected to the gate electrode 43 by a first electrically conductive via 64. The gate finger may adjoin a gate field plate 67 arranged in the insulating layer 51, laterally surrounding the source electrode 52 and connected to the gate runner 53 by a further an electrically conductive via 65. The gate field plate 67, however, may be omitted. In this case, the gate finger 66 is directly connected between the gate electrode 43 and the gate runner 53.

The semiconductor body 100 includes an inner region 110, which is a region that includes the transistor cells 4, and an edge region 120 laterally surrounding the inner region 110. According to one example, the gate runner 53 is arranged above the edge region 120 of the semiconductor body 100.

In the edge region 120, the transistor device may further include an edge termination structure that is configured to absorb a voltage that may occur between the inner region 110 and the sidewalls 103. Usually, the electrical potential of the sidewalls 103 equals drain potential, while the electrical potential of the inner region 110 close to the first surface 101 equals source potential. The edge termination structure is therefore configured to absorb the voltage (drain-source voltage) between the drain node D and the source node S of the transistor device. Edge termination structures of vertical superjunction transistor devices are commonly known, so that an edge termination structure is not illustrated in FIG. 11 and a further explanation is not required in this regard.

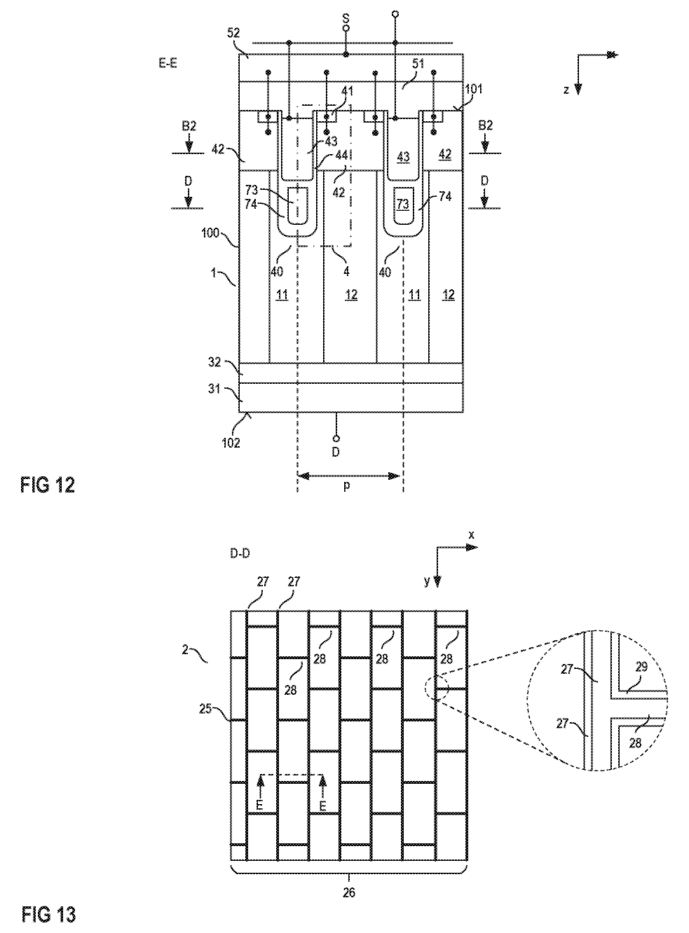

FIG. 12 shows a modification of the transistor cells 4 illustrated in FIG. 1. In the example illustrated in FIG. 12, each transistor cell 4 further includes a field electrode 73 arranged in the gate trench 40. The field electrode 73 is dielectrically insulated from the semiconductor body 100 by a dielectric layer 73 and is arranged adjacent to a respective first region 11 of the superjunction region 1. The field electrode 73 is arranged below the gate electrode 43 in the vertical direction z, as seen from the first surface 101. Furthermore, in the gate trench 40, the field electrode 73 is dielectrically insulated from the gate electrode 43.

In a conventional way, the field electrodes 73 are configured to shape the electric field in the first regions 11 of the superjunction transistor device when the transistor device is in the off-state. For this, each of the field electrodes 73 is either connected to the source node S or the gate node G. The latter is explained herein further below.

According to one example are the field electrodes are formed by longitudinal electrodes 27 of a further trench electrode grid 26 of a trench electrode arrangement 2 of the type explained herein before. A trench electrode grid 20 with longitudinal electrodes 21 forming the gate electrodes 43 of the transistor cells 4 is referred to as first trench electrode grid 20. Longitudinal electrodes 21 of the first trench electrode grid 20 are referred to as first longitudinal electrodes 21, and connection electrodes 22 of the first trench electrode grid 20 are referred to as first connection electrodes 22. The further trench electrode grid 26 with the longitudinal electrodes 27 forming the field electrodes 73 of the transistor cells 4 is referred to as second trench electrode grid 26. The longitudinal electrodes 27 of the second trench electrode grid 26 are referred to as second longitudinal electrodes 27, and connection electrodes 28 of the second trench electrode grid 26 are referred to as second connection electrodes 28.

In a trench electrode arrangement 2 including a first trench electrode grid 20 and a second trench electrode grid 26 each second longitudinal electrode 27 is arranged below a respective first longitudinal electrode 21, and each second connection electrode 28 is arranged below a respective first connection electrode 22. Thus, the second trench electrode grid 26 has the same shape and the same pitch p as the first trench electrode grid 20.

FIG. 13 schematically illustrates a horizontal cross-sectional view in a section plane D-D illustrated in FIG. 12 of a second trench electrode grid 26 according to one example. Just for the purpose of illustration, the second trench electrode grid 26 illustrated in FIG. 1 has the same shape as the first trench electrode grid 20 illustrated in FIG. 4. As can be seen from the detail in FIG. 13, each of the second longitudinal electrodes 27 and the second connection electrodes 28 is dielectrically insulated from the semiconductor body 100 by a dielectric layer 29. The dielectric layer 29 forms the field electrode dielectrics 74 that dielectrically insulate the field electrodes 73 from the semiconductor body 100.

As explained hereinabove, the transistor device may include two or more trench electrode arrangements 2-1, 2-N spaced apart from each other in the first lateral direction x, wherein each trench electrode arrangement 2-1, 2-N includes a respective first trench electrode grid 20-1, 20-N. In addition to the respective first to trench electrode grid 20-1, 20-N each of the two or more trench electrode arrangements 2-1, 2-N may include a respective second trench electrode grid 26-1, 26-N.

FIG. 14 illustrates a horizontal cross-sectional view of second trench electrode grids 26-1, 26-N of several trench electrode arrangements 2-1, 2-N. Just for the purpose of illustration, the several trench electrode arrangements 2-1, 2-N include two trench electrode arrangements in the example illustrated in FIG. 14. This, however, is only an example. The transistor device can be implemented with an arbitrary number of separate trench electrode arrangements 2-1, 2-N.

Just for the purpose of illustration, in the example illustrated in FIG. 14, the second trench electrode grids 26-1, 26-N have the same shape as the first trench electrode grids 20-1, 20-N illustrated in FIG. 5.

Referring to the above, the field electrodes 73 can be connected to the source node S. One example of how the field electrodes 73 can be connected to the source node S is explained with reference to FIGS. 15 and 16 in the following. FIG. 15 shows a top view of a trench electrode arrangement 2 with a first trench electrode grid 20 and a second trench electrode grid 26, and FIGS. 16 shows a vertical cross-sectional view of a first connection electrode 22 of the first trench electrode grid 20 and a second connection electrode 28 of the second trench electrode grid 26.

In the example illustrated in FIGS. 15 and 16, some of the second connection electrodes 28 are connected to the source electrode 52. One second connection electrode 28 connected to the source electrode 52 is illustrated in FIG. 16 in detail.

Referring to FIG. 16 a contact electrode 30 adjoins the second connection electrode 28 and, in the vertical direction z, extends through the first connection electrode 22 arranged above the second connection electrode 28 towards the first surface 101 of the semiconductor body 100. The contact electrode 30 is connected to the source electrode 52 by an electrically conductive via 67 extending from the source electrode 52 through the insulating layer 51 to the contact electrode 30. The contact electrode 30 is dielectrically insulated from the first connection electrode 22 and separates the first connection electrode 22 into sections (portions).

Referring to the above, the second longitudinal electrodes 27 forming the field electrodes 73 of the transistor cells 4 are connected with each other by the second connection electrodes 28. Thus, the field electrodes 73 can be connected to the source electrode 52 by connecting one or more of the second connection electrodes 28 to the source electrode 52.

The grid shaped trench 25 in which the trench electrode arrangement 2 is located includes longitudinal trenches that include the first and second longitudinal electrodes 21, 27 and transversal trenches that include the first and second connection electrodes 22, 28. According to one example, two or more transversal trenches extend between adjacent longitudinal trenches, so that adjacent second longitudinal electrodes 27 are connected by two or more second connection electrodes 28.

If the second longitudinal electrodes 27 are connected to the source electrode 52 in the way illustrated in FIGS. 15 and 16, the second connection electrode 28 in at least one of the transversal trenches connecting two adjacent longitudinal trenches is not connected to the source electrode 52 in order to avoid that the first longitudinal electrodes 21 in the two adjacent longitudinal trenches are electrically isolated from one another. In other words, in at least one the transversal trenches connecting to adjacent longitudinal trenches there is a first connection electrode 22 that connects the first longitudinal electrodes 21 in the adjacent longitudinal trenches and is not interrupted by a contact electrode 30.

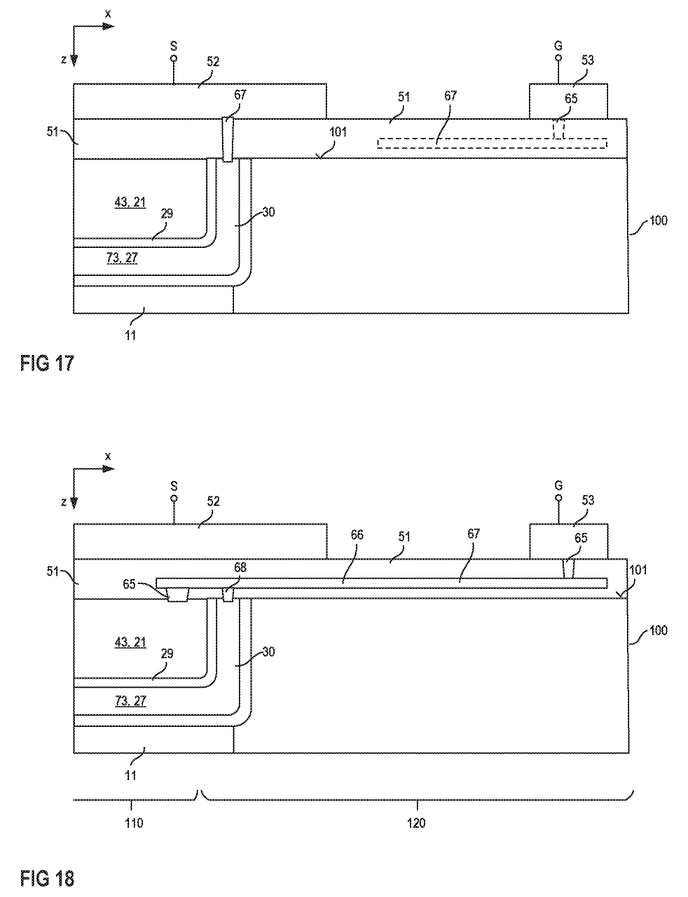

FIG. 17 illustrates another example of how the field electrodes 73 can be connected to the source electrode 52. FIG. 17, similar to the example illustrated in FIG. 11, illustrates a vertical cross-sectional view of a longitudinal trench with first and second longitudinal electrodes 21, 27 arranged therein. FIG. 17 shows the longitudinal trench in a vertical section plane intersecting longitudinal trench in its longitudinal direction. Furthermore, FIG. 17 illustrates a longitudinal end of the longitudinal trench and adjoining portions of the semiconductor body 100 in the region of one longitudinal end of the longitudinal trench.

In the example illustrated in FIG. 17, the contact electrode extends from the second longitudinal trench 27 in the vertical direction z towards the first surface 101 adjacent to the longitudinal end of the first longitudinal electrode 21. The contact electrode 30 is connected to the source electrode 51 by an electrically conductive via 67.

At the same end of the longitudinal trench either the first longitudinal electrode 21 can be connected to the gate runner 53, in the way illustrated in FIG. 11, for example, or the second longitudinal electrode 27 can be connected to the source electrode 52, in the way illustrated in FIG. 17, for example.

According to one example, from the first and second longitudinal electrodes 21, 27 arranged in the same longitudinal trench, the first longitudinal electrode 21 is connected to the gate runner 53 in the region of a first longitudinal end and the second longitudinal electrode 27 is connected to the source electrode 52 in the region of a second longitudinal end of longitudinal trench. According to another example, the trench electrode arrangement includes (a) longitudinal trenches in each which the first longitudinal electrode is connected to the gate runner 53 in the regions of both longitudinal ends, and (b) other longitudinal trenches in each of which the second longitudinal electrode 27 is connected to the source electrode 52 in the regions of both longitudinal ends, where the first longitudinal electrodes 21 in each of the other longitudinal trenches are connected with each other by first connection electrodes 22. Thus, first longitudinal electrodes 21 that are not connected to the gate runner 53 at their longitudinal ends are connected to the gate runner 53 via other first longitudinal electrodes and first connection electrodes 22. Of course, the two examples explained herein before can be combined in order to ensure that each of the first longitudinal electrodes 21 is connected to the gate runner 53 and each of the second longitudinal electrodes 27 is connected to the source electrode 52.

In FIG. 17, the optional gate field plate 67 explained with reference to FIG. 11 is illustrated in dashed lines.

Referring to the above, it is also possible to connect the field electrodes 17 to the gate node G. One example of how the field electrodes 73 can be connected to the gate node G is illustrated in FIG. 18.

The example illustrated in FIG. 18 is based on the example illustrated in FIG. 17, in which the contact electrode 30 extends towards the first surface 101 adjacent to the longitudinal end of the first connection electrode 21. In the example illustrated in FIG. 18, both the first longitudinal electrode 21 and the contact electrode 30 connected to the second longitudinal electrode 27 are connected to the gate runner 53 via the gate finger 66. The contact electrode 30 is connected to the gate finger 66 by an electrically conductive via 68, for example.

Field electrodes 73 connected to the gate node G may increase the gate-drain capacitance of the transistor device, which is the capacitance between the gate node G and the drain node D of the transistor device. Field electrodes 73 connected to the source node S may increase the drain-source capacitance which is the capacitance between the drain node D and the source node S.

According to one example, the transistor device includes two or more gate electrode arrangements 2-1, 2-N each including a first trench electrode grid 20-1, 20-N and a second trench electrode grid 26-1, 26-N and the second trench electrode grid of at least one of the two or more trench electrode arrangements Is connected to the source node S and the second trench electrode grid of at least one of the two or more trench electrode arrangements is connected to the gate node G. Thus, in the example illustrated in FIG. 14, one of the second trench electrode grids 26-1, 26-N may be connected to the source node S in accordance with one of the examples explained with reference to FIGS. 15-17, for example, and the other one of the second trench electrode grids 26-1, 26-N may be connected to the gate node G in accordance with the example explained with reference to FIG. 18, for example.

In a transistor device with a plurality of trench electrode arrangements, the gate-drain capacitance and the train-source capacitance can be adjusted by suitably selecting the number of trench electrode arrangements that have their second trench electrode grid 26 connected to the source node S and suitably selecting the number of trench electrode arrangements that have their second trench electrode grid 26 connected to the gate node G.

One example of a method for forming a superjunction transistor device of the type illustrated in FIG. 1 is explained in the following. The method explained in the following can be applied to forming a superjunction transistor device that includes a trench electrode arrangement with a trench electrode grid. The method, however, is not restricted to forming a superjunction transistor device with a trench electrode grid.

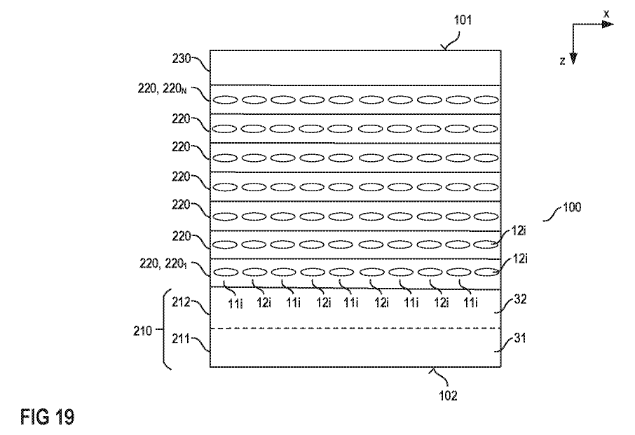

According to one example, forming the superjunction region 1 includes forming a plurality of semiconductor layers one above the other and implanting first type dopant atoms and second type dopant atoms in each of the semiconductor layers. The semiconductor layers are epitaxially grown layers (epitaxial layers) according to one example, so that this type of process is sometimes referred to as multi-epi-multi-implant (MEMI) process. A part of the method for forming the first and second regions 11, 12 using an MEMI process is illustrated in FIG. 19.

FIG. 19 shows a vertical cross-sectional view of a portion of the semiconductor body 100 after forming several semiconductor layers 221 one above the other on top of a carrier 210, and implanting first type dopant atoms and second type dopant atoms into each of the semiconductor layers 221. The first and second type dopant atoms included in a respective one of the semiconductor layers 221 are implanted into the semiconductor layer 221 before the next semiconductor layer 221 is formed (grown).

The semiconductor layers 221 formed above one above the other form a layer stack 220 on top of the carrier 210. The layer stack includes a lowermost semiconductor layer 221₁, which is the semiconductor layer 221 of the layer stack 220 that is produced first, and an uppermost semiconductor layer 221_{N}, which is the semiconductor layer 221 of the layer stack 220 that is produced last in the manufacturing process. The lowermost semiconductor layer 221₁is produced directly on top of the carrier 210.

According to one example, the carrier 210 includes a semiconductor substrate 211 forming the drain region 31 in the finished device and an epitaxial layer 212 grown on top of the substrate 211 and forming the buffer region 32 in the finished device. The epitaxial layer forming the buffer region may be in-situ doped during the epitaxial growth process.

Referring to FIG. 19, implanting the first type dopant atoms into each of the semiconductor layers 220 forms first implanted regions 11i, and implanting the second type dopant atoms into each of the semiconductor layers 221 forms second implanted regions 12i. Referring to FIG. 19 lateral positions of the first implanted regions 11i in the semiconductor layers 221 are selected such that the plurality of first implanted regions 11i form a plurality of groups, each group including one first implanted region 11i in each semiconductor layer 221, and the first implanted regions 11i of each group being arranged one above the other in the vertical direction z. In a similar way, lateral positions of the second implanted regions 12i in the semiconductor layers 221 are selected such that the plurality of second implanted regions 12i form a plurality of groups, each group including one second implanted region 12i in each semiconductor layer 221, and the second implanted regions 12i of each group being arranged one above the other in the vertical direction z.

According to one example, the first and second implanted regions 11i, 12i formed in each of the semiconductor layers 221 do not overlap. According to one example, the first and second implanted regions 11i, 12i formed in each of the semiconductor layers are spaced apart from each other in the first latera direction x.

It should be noted that the implantation processes explained above may take place at wafer level. That is, the implantation processes may take place when a plurality of semiconductor bodies are part of a wafer which is eventually diced to form the individual semiconductor bodies.

In order to form the first and second regions 11, 12 based on the first and second implanted regions 11i, 12i, the method further includes a temperature process (annealing process) that causes the implanted first and second type dopant atoms to diffuse and to be electrically activated.

Implanting the first and second type dopant atoms in the semiconductor layers 221 to form the first and second implanted regions 11i, 12i may include adjusting an implantation energy in the implantation processes such that the first and second type dopant atoms are implanted only into one of the second semiconductor layers 221, 222, namely that one of the semiconductor layers 221 that was produced last before the respective implantation process. As can be seen from FIG. 19, first implanted regions 11i formed one above the other in the vertical direction z may be spaced apart from each other and second implanted regions 12i formed one above the other in the vertical direction z may be spaced apart from each other. In this case, in order to form contiguous first regions 11 and contiguous second regions 12 in the vertical direction z, a diffusion of the implanted first and second type dopant atoms in the vertical direction z in the annealing process is desired. The temperature and the duration of the annealing process are selected such that the desired vertical diffusion of the first and second type dopant atoms is achieved.

It should be noted that the semiconductor body 100 with the carrier 210 and the layer stack 220 with the semiconductor layers 221 is a monocrystalline semiconductor body 100. That is, a border between the carrier 210 and the layer stack 220 and between the individual semiconductor layers 221 in the layer stack 220 is not visible. In FIG. 19, borders between the individual semiconductor layers 221 are only shown for illustration purposes.

The semiconductor layers 221 may be produced (grown) to have a low basic doping concentration before the first and second implanted regions 11i, 12i are formed by implanting first and second type dopant atoms. According to one example, the basic doping concentration is lower than 1E14 cm⁻³ or lower than 1E13 cm⁻³ and may be as low as intrinsic.

The method further includes forming a further semiconductor layer 230, which may be referred to as top layer, on top of the layer stack 220. According to one example, the top layer 230 is an epitaxial layer that has a similar low basic doping as the semiconductor layers 221 of the layer stack 220.

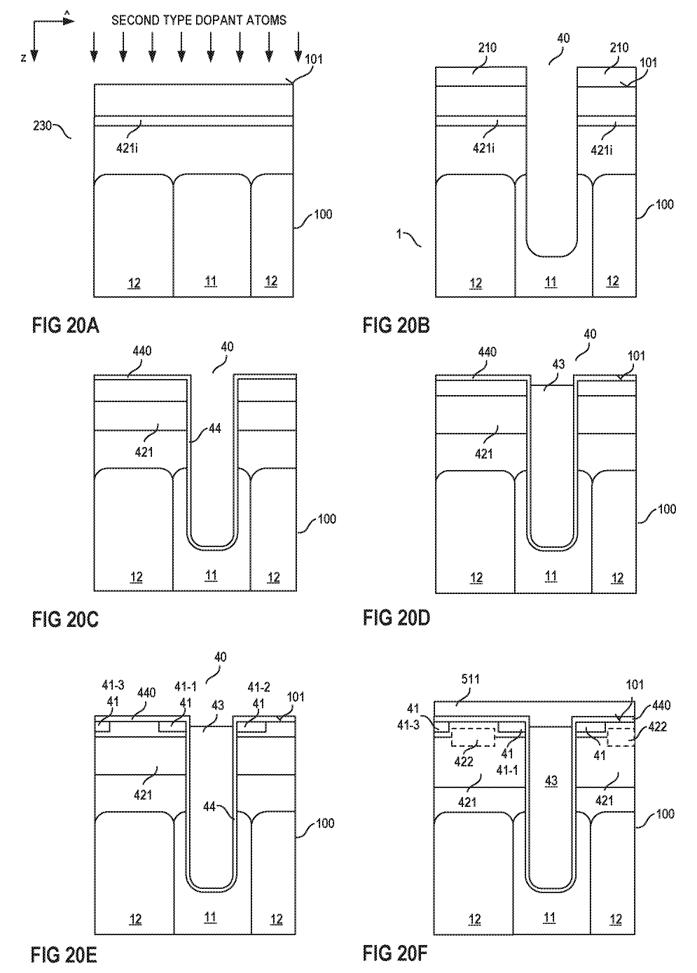

The top layer 230 is the layer in which the transistor cells 4 are substantially formed. A method for forming the transistor cells 4 is explained in the following with reference to FIGS. 20A-20G. Each of FIGS. 20A-20G illustrates a vertical cross-sectional view of one portion of the semiconductor body 100 during the process of forming the transistor cells. In FIGS. 20A-20G substantially one transistor cell is illustrated during the manufacturing process, so that the explanation in the following relates to forming one transistor cell. It should be noted, however, that by the same process a plurality of transistor cells of formed at the same time.

Referring to the above, forming the first and second regions 11, 12 of the superjunction region 1 based on the first and second implanted regions 11i, 12i includes an annealing process. An annealing process for forming the superjunction region 1 based on the first and second implanted regions 11i, 12i may take place before forming the transistor cells 4, so that the first and second regions 11, 12, at least partially, may already have been formed before the manufacturing process for forming the transistor cells 4.

As explained in the following, forming the transistor cells 4 includes one or more further annealing processes. According to one example, only the annealing processes in the process of forming the transistor cells 4 are used to diffuse and electrically activate the dopant atoms included in the superjunction region 1. According to another example, an annealing process for forming the superjunction region 1 is performed before forming the transistor cells and the further annealing process(es) used for forming the transistor cells 4 is additionally used to diffuse the dopant atoms in the superjunction region 1.

Referring to FIG. 20A, the method includes implanting second type dopant atoms in a region of the semiconductor body 100 between the first surface 101 and the superjunction region 1 in order to form a first implanted body region 421i. According to one example illustrated in FIG. 20A, the implantation process includes one implantation step at a certain implantation energy to form one first implanted body region 421i at a desired vertical position. According to one example, the implantation energy is selected such that a peak of a doping concentration of the first implanted body region 421i is spaced apart from the first surface 101. According to one example, the distance between the peak of the doping concentration of the first implanted body region 421i and the first surface 101 is between 400 nanometers and 800 nanometers, in particular between 500 nanometers and 700 nanometers.

According to another example (not illustrated) the implantation process includes two or more implantation steps at different implantation energies in order to form several first implanted body regions having the respective of their doping concentration at different vertical positions.

Referring to FIG. 20B the method further includes, after forming the first implanted region 421i, forming a gate trench 40 extending from the first surface 101 through the first implanted regions 421i to the superjunction region 1. More specifically, the gate trench 40 extends into one of the first regions (drift regions) 11 of the superjunction region 1. Forming the gate trench 40 may include a conventional etching process, such as an anisotropic etching process, using an etch mask 210 formed above the first surface 101 of the semiconductor body 100.

The trench width, which is the dimension of the gate trench 40 in the first lateral direction x is selected from between 800 nanometers and 1.2 micrometers, in particular between 900 nanometers and 1.1 micrometers, for example. The trench depth, which is the dimension of the gate trench 40 in the vertical direction is selected from between 2 micrometers and 6 micrometers, in particular between 2 micrometers and 4 micrometers, for example.

Referring to FIG. 20C, the method further includes forming the gate dielectric 44 on surfaces of the gate trench 40. This includes forming a gate dielectric layer 440 on the surfaces of the gate trench 40 and on top of the first surface 101 of the semiconductor body 100. The gate dielectric layer 440 entirely covers the surfaces inside the gate trench 40, so that the gate dielectric 44 dielectrically insulates the surrounding semiconductor body 100 from the gate electrode to be formed in the gate trench 40.

Referring to FIG. 20D, the method further includes forming the gate electrode 43 in the gate trench 40. According to one example, the gate electrode 43 is formed to be recessed in the gate trench 40. This includes, that an upper surface of the gate electrode 43 is spaced apart from a vertical position of the first surface 101 of the semiconductor body 100. Examples for forming the gate electrode are explained herein further below.

Referring to FIG. 20E, the method further includes forming the source region 41 of the transistor cell. Referring to FIG. 1, source regions 41 of two transistor cells 4 sharing the same gate electrode 43 may be arranged on opposite sides of one gate trench including the common gate electrode 43. Furthermore, as can be seen from FIG. 1, source regions of two transistor cells sharing a body region 42 can be arranged in the same semiconductor mesa region spaced apart from each other in the first lateral direction x. The mesa region is the region between two adjacent gate electrode trenches 40.

FIG. 20E illustrates source regions of three different transistor cells. A first source region 41-1 and a second source region 41-2 of the three source regions 41 adjoin the gate trench 40 with the gate dielectric 44 and the gate electrode 43 on opposite sides. A third source region 41-3 is arranged in the same mesa region as the first source region 41-1 and spaced apart from the first source region 41-1in the first lateral direction x. Forming the source regions 41 may include implanting first type dopant atoms using an implantation mask (not illustrated) via the first surface 101 into the semiconductor body 100, and an annealing process to electrically activate the implanted first type dopant atoms and form the source regions 41.

Forming the gate dielectric 44 includes a thermal oxidation process in which at least a portion of the gate dielectric 44 is formed. The temperature involved in this thermal oxidation process and possible other thermal processes that may take place before forming the source regions 41 cause second type dopant atoms in the first implanted body region 421i to diffuse and to be electrically activated, so as to form a first portion 421 of the body region 42 of the transistor cell. According to one example, the source regions 41 are formed, in the vertical direction z, between the first surface 101 and the first body region portion 421.

The annealing process involved in forming the source regions 41 may cause the second type dopant atoms included in the first body region portion 421 to diffuse further. The annealing process for forming the source regions 41, however, may be selected such that it activates the implanted dopant atoms but substantially avoids a diffusion of the implanted dopant atoms. Thus, this annealing process can be relatively short.

Referring to FIG. 20F, optionally, the method further includes forming a second body region portion 422 (illustrated with dashed lines) at least partially in a region between the first surface 101 and the first body region portion 421. The second body region portion 422, in the first lateral direction x, is arranged between the source regions (the first and third source regions 41-1, 41-1 in the example illustrated in FIG. 20F) arranged in the same mesa region. Forming the second body region portion 422 may include implanting second type dopant atoms via the first surface 101 into the semiconductor body 100 using an implantation mask (not illustrated), and an annealing process.

According to one example illustrated in FIG. 20F, the second body region portion 422 is formed after forming a first insulating layer 511 on top of the gate dielectric layer 440. The first insulating layer 511 covers the gate dielectric layer 440 above the first surface 101 and covers the gate electrode 43 in the gate trench 40. The first insulating layer 511 is a deposited layer. The deposited layer is a deposited oxide layer, for example. In this example, the second type dopant atoms for forming the second body region portion 422 are implanted through the first insulating layer 511 and the gate dielectric layer 440.

Referring to FIG. 20G, the method further includes forming a second insulating layer 512 on top of the first insulating layer 511, and forming the electrically conductive vias 61 and the optional further electrically conductive via 61' to extend through the first and second insulating layers 511, 512 and the gate dielectric layer 440 into the semiconductor body 100. The electrically conductive vias 61 are formed such that each of the electrically conductive vias 61 adjoins a respective source region 41 and at least one of the first and second body region portions 421, 422. The optional further electrically conductive via 61' is formed such that it adjoins at least one of the first and second body region portions 421, 422. Furthermore, the method includes forming the source electrode 52 on top of the second insulating layer 512 and in electrical contact with the electrically conductive vias 61 and the optional further electrically conductive via 61'.

The second insulating layer 512 is a deposited layer. The second insulating layer 512 may be a homogeneous layer from one material. According to another example, the second insulating layer 512 includes two or more sub-layers formed one above the other. According to one example, one of the sub-layers is an oxide layer based on TEOS (tetraethoxysilane), and the other one of the sublayers is a glass layer, such as a BPSG (borophosphosilicate glass) layer.

In the example illustrated in FIG. 20G, the body region 42 is formed by the first and second body region portions 421, 422. Furthermore, the insulating layer 51 between the source electrode 52 and the semiconductor body 100 is formed by the first and second insulating layers 511, 512 and the gate dielectric layer 440.

As explained with reference to FIGS. 7 and 8, each transistor cell 4 may further include a contact region 45 of the second doping type that provides for an ohmic connection between the electrically conductive via 61 and the body region 42. The contact regions 45 may be formed by forming trenches in the insulating layer 51 and implanting second type dopant atoms via the trenches into the semiconductor body 100 before forming the vias 61. Forming the contact regions 45 based on the implanted second type dopant atoms further includes an annealing process. This annealing process may take place before or after forming the vias 61 or during the process of forming the vias in the via trenches.

According to one example, the second body region portion 422 mainly serves to connect the body region 42 to the vias 61 and the source electrode 52. In each of the thermal processes that take place after forming the first implanted body region 421i the first dopant atoms included in the first implanted body region 421i diffuse. A distance between the first surface 101 and the first body region portion 421 is dependent on the vertical position of the first implanted body region 421i after the implantation process and the thermal budget in the thermal processes that diffuse the first type dopant atoms included in the first implanted body region 421i.

According to one example, the first implanted body region 421 extends to the position of the contact regions 45 after the thermal processes. In this example, forming the second body region portion 422 is not absolutely necessary.

As explained before, each of the thermal processes that takes place after forming the first implanted body region 421i partially diffuses the first type dopant atoms included in the first implanted body region 421i. Thus, over the process of forming the transistor cells 4 the first body region portion 421 expands in the vertical direction z. According to one example, the vertical position of the peak of the doping concentration of the first implanted regions 421i and the thermal budget of the thermal processes that take place after forming the first implanted regions 421i are adapted to one another such that the first body region portion 421 in the finished transistor device extends to the second regions (compensation regions) 12 of the superjunction region 1 in order to connect the second regions 12 to the source electrode 52. The thermal budget of the thermal process is dependent on the temperature and the duration of the individual thermal processes.

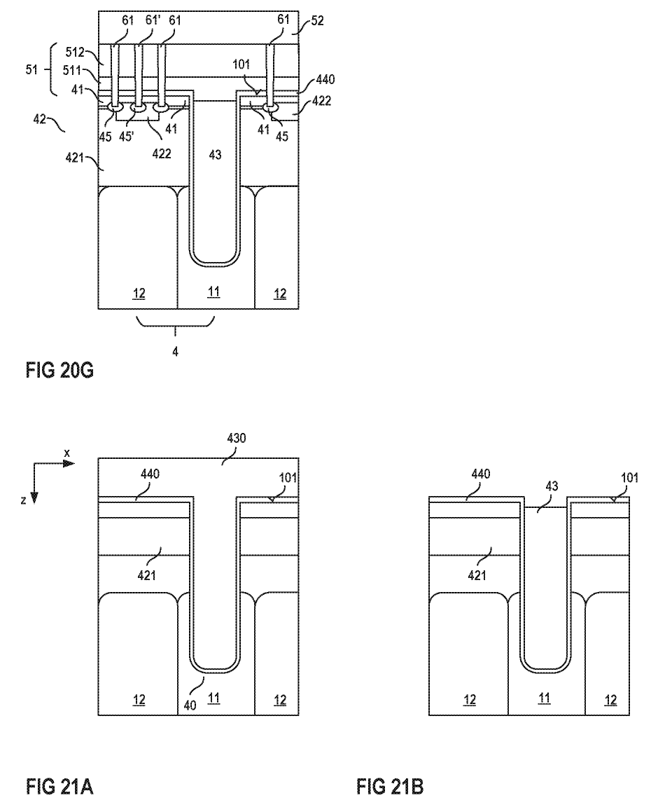

FIGS. 21A-21B illustrate one example of a method for forming the gate electrode 43. Referring to FIG. 21A, the method includes forming a gate electrode layer 430 such that the gate electrode layer 430 fills the gate trench 40 and covers the gate dielectric layer 440 above the first surface 101 of the semiconductor body 100. Referring to FIG. 21B, the method further includes removing the gate electrode layer 430 from above the first surface 101 of the semiconductor body 100 and removing the gate electrode layer 430 from an upper portion of the gate trench 40, so that the gate electrode 43 is recessed relative to the first surface 101 of the semiconductor body 100. The gate electrode layer 430 is an electrically conductive layer, such as a highly doped polysilicon layer or a metal layer, for example.

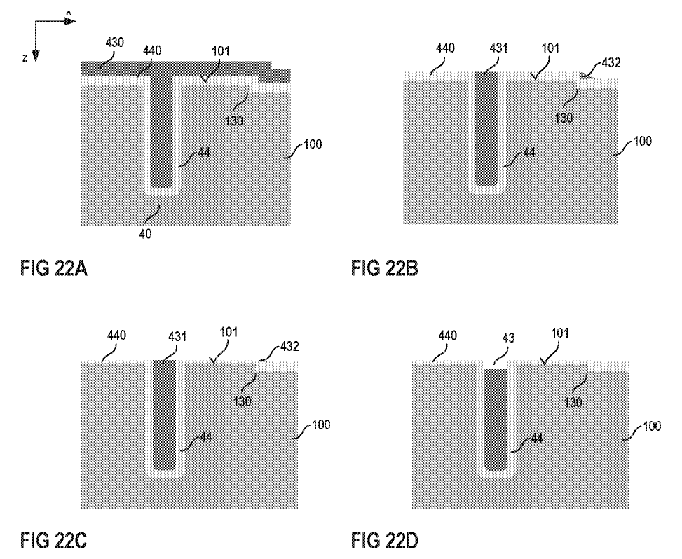

FIGS. 22A-22D illustrate one example of the method for forming the gate electrode 43 based on the gate electrode layer 430 in greater detail. Each of FIGS. 22A-22D shows a vertical cross-sectional view of the gate trench 40 filled with the gate electrode layer 430. Semiconductor regions, such as source and body regions or the superjunction region, are not illustrated.

FIG. 22A shows the semiconductor body with the gate trench 40 after forming the gate electrode layer 430 above the first surface 101 of the semiconductor body 100 and in the gate trench 40. In the example illustrated in FIGS. 22A-22D, the first surface 101 of the semiconductor body 100 includes a step 130 at a position spaced apart from the gate trench 40. Such step in the first surface 101 may result from other process steps in the manufacturing process not explained here. The step 130 in the first surface 101 results in a corresponding step in the gate dielectric layer 440 and the gate electrode layer 430.

Referring to FIG. 22B, the method includes a planarizing process which at least partially removes the gate electrode layer 430 from above the gate dielectric layer 440. In this context, at least partially, includes that residuals 432 of the gate electrode layer 430 may remain on top of the gate dielectric layer 440 in the region of the step 130.

Referring to FIG. 22C, the method further includes a first etching process. According to one example, the first etching process is configured to etch both the material of the gate electrode layer 430 and the material of the gate dielectric layer 440, so that the first etching process removes portions of the gate dielectric layer 440 from above the first surface 101 and at least portions of the residuals 432 which may have remained after the planarizing process. The first etching process may be configured to adjust a desired thickness of the gate dielectric layer 440.

Referring to FIG. 22D, the method further includes a second etching process. According to one example, the second etching process is configured to substantially etch the material of the gate electrode layer 430 selectively relative to the material of the gate dielectric layer 440. Thus, the second etching process does not further reduce the thickness of the gate dielectric layer 440 on top of the first surface 101, but etches the material of the gate electrode layer 430 in the gate trench 40, so that the gate electrode 43 is recessed relative to the first surface 101 after the second etching process.

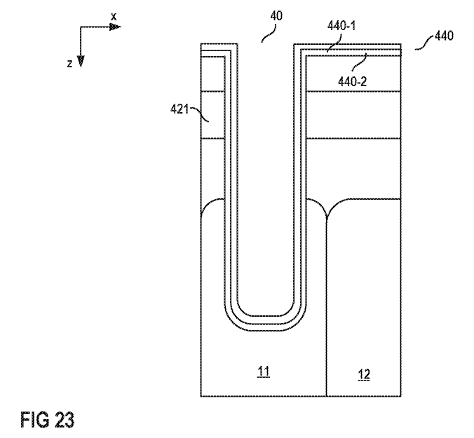

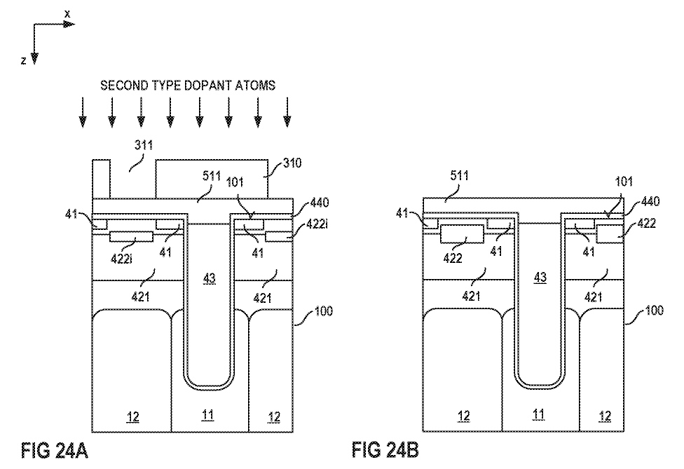

According to one example illustrated in FIG. 23, the gate dielectric layer 440 includes a thermally grown oxide layer 440-1 and a deposited oxide layer 440-2, such as a TEOS based layer, on top of the thermally grown oxide layer 440-1. As explained before, the thermal process involved in the process of forming the gate dielectric layer 440 is used to electrically activate and diffuse the second type dopant atoms included in the first implanted body region 421i. By only partially forming the gate dielectric layer 440 as a thermally grown oxide layer the thermal budget of forming the gate dielectric layer 440 and thus the thermal budget for activating and diffusing the second type dopant atoms can be adjusted more precisely.

FIGS. 24A-24B illustrate one example of a method for forming the second body region portion 422. Referring to FIG. 24A, the method includes implanting second type dopant atoms using an implantation mask 311 into the semiconductor body 100 to form a second implanted body region 422i. The method further includes an annealing process in order to form the second body region portion 422 based on the second implanted body region 422i, as illustrated in FIG. 24B.

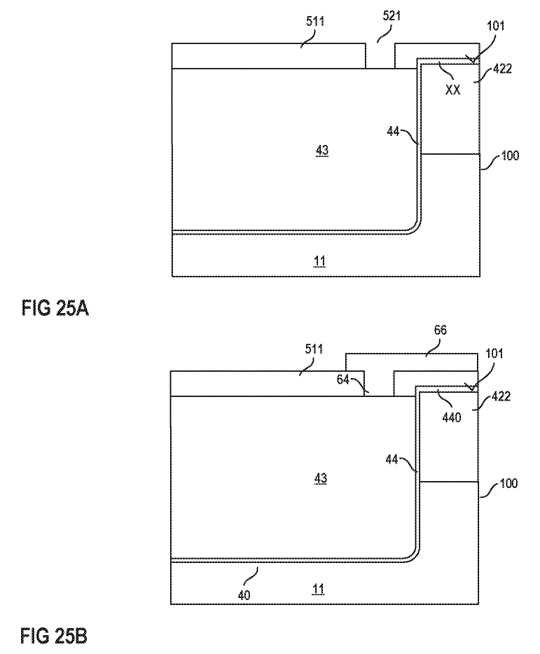

As explained above, the gate electrodes 43 can be connected to the gate runner 53 by gate fingers 66 connected to longitudinal ends of the gate electrodes 43. One example of a method for forming a gate finger 66 and the via 64 connecting the gate finger 66 to the gate electrode 43 is illustrated in FIGS. 25A-25B, each of which illustrates a vertical cross-sectional view of a gate electrode 43 in a section plane intersecting the gate electrode 43 in the longitudinal direction.

FIG. 25A shows the gate electrode 43 after forming the gate dielectric layer 440 and the first insulating layer 511 covering the gate electrode 43 in the gate trench 40.

Referring to FIG. 25B, the method further includes forming an opening in the first insulating layer 511 above the gate electrode 43 and forming the electrically conductive via 64 in the opening and the gate finger 66 on top of portions of the first insulating layer 511. Forming the gate finger 66 and the via 64 may include depositing an electrically conductive layer that covers the first insulating layer 511 and fills the opening in the first insulating layer 511, and patterning the electrically conductive layer to form the gate finger 66. According to one example, the electrically conductive layer forming the gate finger 66 and the via 64 is a highly doped polysilicon layer, such as an N-doped polysilicon layer.

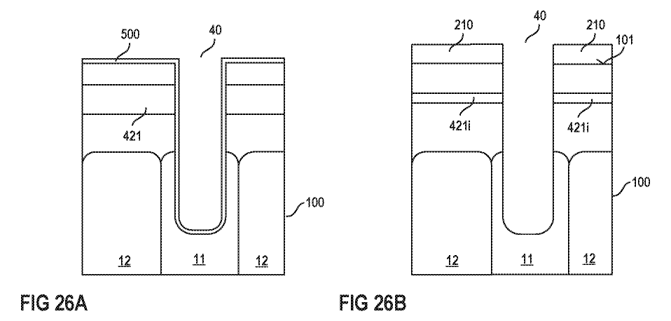

According to one example illustrated in FIGS. 26A-26B, the method further includes a sacrificial oxidation process before forming the gate dielectric 44. Each of FIGS. 26A-26B illustrates a vertical cross-sectional view of one portion of the semiconductor body 100 during the process of forming the transistor cells.

Referring to FIG. 26A, the sacrificial oxidation process includes forming a sacrificial oxide layer 500 in a thermal oxidation process on surfaces of the gate trench 40 and on the first surface 101 of the semiconductor body 100. Referring to FIG. 26B, the sacrificial oxide layer 500 is removed before the gate dielectric 44 (not shown in FIG. 26B) is formed.

Some of the aspects explained above are briefly summarized in the following with reference to numbered examples.

Example 1. A transistor device, including: a superjunction region including first regions of a first doping type and second regions of a second doping type complementary to the first doping type, the first regions and the second regions being arranged alternately in a lateral direction of a semiconductor body; transistor cells each including a gate electrode arranged in a gate trench and dielectrically insulated from the semiconductor body by a gate dielectric, a source region, and a body region; and a trench electrode arrangement including a first trench electrode grid arranged in a grid-shaped trench of the semiconductor body and insulated from the semiconductor body by a dielectric layer, wherein the first trench electrode grid includes: first longitudinal electrodes spaced apart from each other in a first lateral direction of the semiconductor body; and first connection electrodes each connecting two adjacent first longitudinal electrodes, and wherein the gate electrodes of at least some of the transistor cells are formed by the first longitudinal electrodes of the trench electrode grid.

Example 2. The transistor device of example 1, wherein a center-to-center distance between adjacent longitudinal electrodes is selected from between 3 micrometers and 4.5 micrometers, in particular between 3 micrometers and 3.5 micrometers.

Example 3. The transistor device of example 1 or 2, wherein two adjacent longitudinal electrodes are connected by several of connection electrodes spaced apart from each other in a second lateral direction of the semiconductor body.

Example 4. The transistor device of example 3, wherein a center-to-center distance between adjacent connection electrodes in the second lateral direction is selected from between 30 micrometers and 200 micrometers, in particular between 40 micrometers and 100 micrometers.

Example 5. The transistor device of any one of examples 1 to 4, wherein the source region is spaced apart from each of the connection electrodes.

Example 6. The transistor device of any one of examples 1 to 5, wherein each transistor cell further includes a field electrode arranged in the gate trench below the gate electrode, as seen from a first surface of the semiconductor body, wherein the trench electrode arrangement further includes a second trench electrode grid arranged in the grid-shaped trench of the semiconductor body and insulated from the semiconductor body by a dielectric layer, wherein the second trench electrode grid includes: second longitudinal electrodes each arranged below a respective one of the first longitudinal electrodes; and second connection electrodes each arranged below a respective one of the first connection electrodes and each connecting two adjacent second longitudinal electrodes, and wherein the field electrodes of at least some of the transistor cells are formed by the second longitudinal electrodes of the second trench electrode grid.

Example 7. The transistor device of any one of examples 1 to 6, further including: a gate node connected to the gate electrodes of the transistor cells; and a source node connected to the source and body regions of the transistor cells.

Example 8. The transistor device of example 6 or 7, wherein the field electrodes are connected to the source node.

Example 9. The transistor device of example 6 or 7, wherein the field electrodes are connected to the gate node.

Example 10. The transistor device of example 6 or 7, wherein the trench electrode arrangement is a first trench electrode arrangement, wherein the transistor device further includes at least one further trench electrode arrangement, wherein the second trench electrode grid of at least one of the first trench electrode arrangement and the further trench electrode arrangement is connected to the gate node, and wherein the second trench electrode grid of at least another one of the first trench electrode arrangement and the further trench electrode arrangement is connected to the source node.

Example 11. The transistor device of any one of examples 1 to 10, wherein each gate trench, in a vertical direction of the semiconductor body extends into a respective one of the first regions.

Example 12. The transistor device of any one of examples 1 to 11, wherein the lateral direction in which the first and second regions of the superjunction region are arranged alternately equals the first lateral direction.

Example 13. A method for forming a superjunction transistor device, the method including: forming a superjunction region in a semiconductor body, the superjunction region including first regions of a first doping type and second regions of a second doping type complementary to the first doping type; and forming a plurality of transistor cells, wherein forming each transistor cell includes: implanting second type dopant atoms in a region between a first surface of the semiconductor body and the superjunction region to form a first implanted body region; forming a gate trench extending from the first surface through the first implanted region to the superjunction region; forming a gate dielectric in the gate trench, forming the gate dielectric including a thermal oxidation process that causes a first body region portion to be formed based on the first implanted body region; forming a gate electrode in the gate trench on top of the gate dielectric; and forming a source region in the semiconductor body, the source region adjoining the gate dielectric.

Example 14. The method of example 13, further including: forming a second body region portion next to the source region in a lateral direction and arranged closer to the first surface than the first body region portion

Example 15. The method of example 13, wherein forming the gate dielectric includes: forming a gate dielectric layer on surfaces of the gate trench and on top of the first surface of the semiconductor body.

Example 16. The method of example 15, further including: forming a first insulating layer covering the gate dielectric layer above the first surface and the gate electrode.

Example 17. The method of example 16, wherein forming the second body region portion includes implanting second type dopant atoms through the first insulating layer and the gate dielectric layer in the semiconductor body to form a second implanted body region.

Example 18. The method of example 16 or 17, further including: forming a second insulating layer on top of the first insulating layer; forming at least one electrically conductive via extending through the first and second insulating layers and the gate dielectric layer into the semiconductor body, the at least one electrically conductive via electrically connected to the source region and at least one of the first and second body region portions; and forming a source electrode on top of the second insulating layer.

Example 19. The method of any one of examples 13 to 18, further including: forming a sacrificial oxide layer in a thermal oxidation process on surfaces of the gate trench and on the first surface of the semiconductor body; and removing the sacrificial oxide layer before forming the gate dielectric.

Example 20. The method of any one of examples 13 to 19, wherein forming the gate dielectric includes: forming an oxide layer on the surfaces of the gate trench and on the first surface of the semiconductor body in a thermal excitation process; and depositing a dielectric layer on top of the oxide layer.

Example 21. The method of example 20, wherein the dielectric layer is an oxide layer.

Example 22. The method of any one of examples 13 to 21, wherein forming the gate electrode includes: depositing a gate electrode layer on top of a gate dielectric layer; removing the gate electrode layer from above the first surface of the semiconductor body and from an upper section of the gate trench.

Example 23. The method of example 22, wherein removing the gate electrode layer from above the first surface of the semiconductor body and from an upper section of the gate trench includes: a planarization process removing at least portions of the gate electrode layer from above the first surface of the semiconductor body; a first etching process configured to etch the gate electrode layer and the gate dielectric layer, the first etching process removing a portion of the gate dielectric layer from above the first surface; and a second etching process configured to etch the gate electrode layer selectively relative to the gate dielectric layer, the second etching process removing the gate electrode layer from the upper section of the gate trench.

Example 24. The method of example 23, wherein the first surface of the semiconductor body includes a step spaced apart from the gate trench; and wherein at least one of the first etching process and the second etching process removes a portion of the gate electrode layer on top of the gate dielectric layer in the region of the step.

Example 25. The method of any one of examples 13 to 24, wherein the gate trench is a longitudinal trench of a grid-shaped trench including longitudinal trenches and transversal trenches.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device, comprising:
a superjunction region comprising a plurality of first regions of a first doping type and a plurality of second regions of a second doping type complementary to the first doping type, the first regions and the second regions being arranged alternately in a lateral direction of a semiconductor body;
a plurality of transistor cells each comprising a gate electrode arranged in a gate trench and dielectrically insulated from the semiconductor body by a gate dielectric, a source region, and a body region; and
a trench electrode arrangement comprising a first trench electrode grid arranged in a grid-shaped trench of the semiconductor body and insulated from the semiconductor body by a dielectric layer,
wherein the first trench electrode grid comprises:
a plurality of first longitudinal electrodes spaced apart from each other in a first lateral direction of the semiconductor body; and
a plurality of first connection electrodes each connecting two adjacent ones of the first longitudinal electrodes,
wherein the gate electrodes of at least some of the transistor cells are formed by the first longitudinal electrodes of the trench electrode grid.

2. The transistor device of claim 1, wherein a center-to-center distance between adjacent ones of the first longitudinal electrodes is selected from between 3 micrometers and 4.5 micrometers.

3. The transistor device of claim 1, wherein the two adjacent ones of the first longitudinal electrodes are connected by several of the first connection electrodes spaced apart from each other in a second lateral direction of the semiconductor body.

4. The transistor device of claim 3, wherein a center-to-center distance between adjacent ones of the first connection electrodes in the second lateral direction is selected from between 30 micrometers and 200 micrometers.

5. The transistor device of claim 1, wherein the source region is spaced apart from each of the first connection electrodes.

6. The transistor device of claim 1, wherein:
each transistor cell further comprises a field electrode arranged in the gate trench below the gate electrode, as seen from a first surface of the semiconductor body;
the trench electrode arrangement further comprises a second trench electrode grid arranged in the grid-shaped trench of the semiconductor body and insulated from the semiconductor body by a dielectric layer;
the second trench electrode grid comprises:
a plurality of second longitudinal electrodes each arranged below a respective one of the first longitudinal electrodes; and
a plurality of second connection electrodes each arranged below a respective one of the first connection electrodes and each connecting two adjacent ones of the second longitudinal electrodes, and
the field electrodes of at least some of the transistor cells are formed by the second longitudinal electrodes of the second trench electrode grid.

7. The transistor device of claim 1, further comprising:
a gate node connected to the gate electrodes of the transistor cells; and
a source node connected to the source and body regions of the transistor cells.

8. The transistor device of claim 7, wherein the field electrodes are connected to the source node.

9. The transistor device of claim 7, wherein the field electrodes are connected to the gate node.

10. The transistor device of claim 7, wherein:
the trench electrode arrangement is a first trench electrode arrangement;
the transistor device further comprises at least one further trench electrode arrangement;
the second trench electrode grid of at least one of the first trench electrode arrangement and the further trench electrode arrangement is connected to the gate node; and
the second trench electrode grid of at least another one of the first trench electrode arrangement and the further trench electrode arrangement is connected to the source node.

11. The transistor device of claim 1, wherein each gate trench, in a vertical direction of the semiconductor body, extends into a respective one of the first regions.

12. The transistor device of claim 1, wherein the lateral direction in which the first and second regions of the superjunction region are arranged alternately equals the first lateral direction.

13. A method for forming a superjunction transistor device, the method comprising:
forming a superjunction region in a semiconductor body, the superjunction region comprising a plurality of first regions of a first doping type and a plurality of second regions of a second doping type complementary to the first doping type; and
forming a plurality of transistor cells, wherein forming each transistor cell comprises:
implanting second type dopant atoms in a region between a first surface of the semiconductor body and the superjunction region to form a first implanted body region;
forming a gate trench extending from the first surface through the first implanted region to the superjunction region;
forming a gate dielectric in the gate trench, wherein forming the gate dielectric comprises a thermal oxidation process that causes a first body region portion to be formed based on the first implanted body region;
forming a gate electrode in the gate trench on top of the gate dielectric; and
forming a source region in the semiconductor body, the source region adjoining the gate dielectric.

14. The method of claim 13, further comprising:
forming a second body region portion next to the source region in a lateral direction and arranged closer to the first surface than the first body region portion.

15. The method of claim 13, wherein forming the gate dielectric comprises:
forming a gate dielectric layer on surfaces of the gate trench and on top of the first surface of the semiconductor body.

16. The method of claim 15, further comprising:
forming a first insulating layer covering the gate dielectric layer above the first surface and the gate electrode.

17. The method of claim 16, wherein forming the second body region portion comprises implanting second type dopant atoms through the first insulating layer and the gate dielectric layer in the semiconductor body to form a second implanted body region.

18. The method of claim 16, further comprising:
forming a second insulating layer on top of the first insulating layer;
forming at least one electrically conductive via extending through the first and second insulating layers and the gate dielectric layer into the semiconductor body, the at least one electrically conductive via being electrically connected to the source region and at least one of the first and second body region portions; and
forming a source electrode on top of the second insulating layer.

19. The method of claim 13, further comprising:
forming a sacrificial oxide layer in a thermal oxidation process on surfaces of the gate trench and on the first surface of the semiconductor body; and
removing the sacrificial oxide layer before forming the gate dielectric.

20. The method of claim 13, wherein forming the gate dielectric comprises:
forming an oxide layer on surfaces of the gate trench and on the first surface of the semiconductor body in a thermal excitation process; and
depositing a dielectric layer on top of the oxide layer.

21. The method of claim 20, wherein the dielectric layer is an oxide layer.

22. The method of claim 13, wherein forming the gate electrode comprises:
depositing a gate electrode layer on top of a gate dielectric layer; and
removing the gate electrode layer from above the first surface of the semiconductor body and from an upper section of the gate trench.

23. The method of claim 22, wherein removing the gate electrode layer from above the first surface of the semiconductor body and from the upper section of the gate trench comprises:
a planarization process removing at least portions of the gate electrode layer from above the first surface of the semiconductor body;
a first etching process configured to etch the gate electrode layer and the gate dielectric layer, the first etching process removing a portion of the gate dielectric layer from above the first surface; and
a second etching process configured to etch the gate electrode layer selectively relative to the gate dielectric layer, the second etching process removing the gate electrode layer from the upper section of the gate trench.

24. The method of claim 23, wherein:
the first surface of the semiconductor body comprises a step spaced apart from the gate trench; and
at least one of the first etching process and the second etching process removes a portion of the gate electrode layer on top of the gate dielectric layer in the region of the step.

25. The method of claim 13, wherein the gate trench is a longitudinal trench of a grid-shaped trench including longitudinal trenches and transversal trenches.
